(19) United States
(12) Patent Application Publication
(10) Pub. No.: US 2023/0395766 A1
(43) Pub. Date: Dec. 7, 2023

(54) MOUNTING BOARD AND CIRCUIT BOARD

(71) Applicant: TDK CORPORATION, Tokyo (JP)

(72) Inventors: Tomohisa MITOSE, Tokyo (JP); Kenichi KAWABATA, Tokyo (JP); Susumu TANIGUCHI, Tokyo (JP); Akiko SEKI, Tokyo (JP)

(73) Assignee: TDK CORPORATION, Tokyo (JP)

(21) Appl. No.: 18/032,212

(22) PCT Filed: Oct. 14, 2021
(86) PCT No.: PCT/JP2021/038082

§ 371 Date: Apr. 17, 2023

(30) Foreign Application Priority Data
Oct. 19, 2020 (JP) 2020-175233

(51) Int. Cl. H01L 33/62; H01L 23/00; H05K 1/18

(52) U.S. Cl. CPC H01L 33/62; H01L 24/16; H01L 24/13; H05K 1/181; H01L 24/73; H01L 24/32; H01L 2933/0066; H01L 2224/73204; H01L 2224/32237; H01L 24/81; H01L 2224/16237; H01L 2224/13111; H01L 2224/13113; H01L 2224/81815; H01L 2224/81192; H05K 2201/10106; H05K 2201/09472; H01L 2924/12041; H05K 2201/09827

(57) ABSTRACT

A mounting board includes an electronic component having at least a pair of first terminals, and a circuit board having at least a pair of second terminals. The first terminal and the second terminal are bonded to each other by a bonding material. The first terminal, the second terminal, and the bonding material are disposed inside a recessed portion formed in a resin layer such that the periphery thereof is surrounded by the resin layer. When a total thickness of the first terminal, the second terminal, and the bonding material is a dimension h1, the dimension h1 is 1 μm to 20 μm. When a width of the first terminal is a dimension d1 and a width of the recessed portion of the resin layer is a dimension d2, a value of (dimension d2—dimension d1) is 10 μm or smaller.

### TECHNICAL FIELD

The present disclosure relates to a mounting board and a circuit board.

### BACKGROUND ART

Electronic components are often mounted on circuit boards with a solder therebetween. When an electronic component is mounted on a circuit board using a solder, a solder ball may be formed in a reflow step, and this may cause a problem of a short circuit between a pair of terminals of the electronic component due to the solder ball. In order to resolve such a problem, a technology of forming a projection between a pair of terminals has been disclosed (Patent Literature 1).

### CITATION LIST

### Patent Literature

[Patent Literature 1] Japanese Unexamined Patent Publication No. 2006-286851

### SUMMARY OF INVENTION

### Technical Problem

In recent years, along with miniaturization of electronic instruments, miniaturization of electronic components used in electronic instruments has also progressed. For example, there is a growing demand for mounting boards, such as micro LEDs, in which an electronic component of approximately 20 μm is mounted on a circuit board. However, as electronic components become smaller, there is a need to use a smaller solder, but it is difficult to control the amount of solder, and the amount of solder for bonding may vary. For this reason, the solder size varies, the balance between forces holding an electronic component collapses, and stress is applied to the solder after bonding, resulting in an insufficient strength in many cases. Accordingly, there is a problem that an electronic component is likely to peel off from a circuit board due to a physical impact applied thereto.

An object of the present disclosure is to provide a mounting board in which an electronic component can be unlikely to peel off from a circuit board, and a circuit board.

### Solution to Problem

Amounting board according to the present disclosure includes an electronic component having at least a pair of first terminals, and a circuit board having at least a pair of second terminals. The first terminal and the second terminal are bonded to each other by a bonding material. The first terminal, the second terminal, and the bonding material are disposed inside a recessed portion formed in a resin layer such that the periphery thereof is surrounded by the resin layer. When a total thickness of the first terminal, the second terminal, and the bonding material is a dimension h1, the dimension h1 is 1 μm to 20 μm. When a width of the first terminal is a dimension d1 and a width of the recessed portion of the resin layer is a dimension d2, a value of (dimension d2—dimension d1) is 10 μm or smaller.

In the mounting board according to the present disclosure, the first terminal, the second terminal, and the bonding material are disposed inside the recessed portion formed in the resin layer such that the periphery thereof is surrounded by the resin layer. Accordingly, an impact cushioning structure of the resin layer can be provided around a bonded part. Moreover, the bonded part can be unlikely to break by setting the dimension h1, which is the total thickness of the first terminal, the second terminal, and the bonding material, to 1 μm to 20 μm. In addition, by setting the value of (dimension d2-dimension d1) to be 10 μm or smaller, the electronic component can be unlikely to peel off from the circuit board when the mounting board has received a physical impact.

A constituent material may be disposed between the bonding material and the resin layer. Accordingly, the electronic component can be less likely to peel off from the circuit board by being supported by the constituent material.

A constituent material may be disposed between the resin layer present between the pair of first terminals and a main body portion of the electronic component. Accordingly, the main body portion of the electronic component can be held by the constituent material, and thus the strength can be improved.

The constituent material may come into contact with the main body portion. In this case, a lower surface of the main body portion of the electronic component can be fixed by the constituent material. Therefore, even if the mounting board receives a physical impact, a force is unlikely to be applied to the bonding material so that the electronic component is unlikely to peel off from the circuit board.

The resin layer present between the pair of first terminals may come into contact with a main body portion of the electronic component. In this case, since the lower surface of the main body portion of the electronic component is supported by the resin layer by coming into contact therewith, even if the mounting board receives a physical impact, a force is unlikely to be applied to the bonding material so that the electronic component is unlikely to peel off from the circuit board.

When a height of the resin layer present between the pair of first terminals is a dimension R1 and a height of the resin layer surrounding the electronic component is a dimension R2, the dimension R1 may be smaller than the dimension R2. In this case, since the main body portion of the electronic component is constituted to be surrounded and supported by the surrounding resin layer, even if the mounting board receives a physical impact, a force is unlikely to be applied to the bonding material so that the electronic component is unlikely to peel off from the circuit board.

An inner side surface of the recessed portion may have a tapered shape. Although a force is applied from the resin layer to the bonding material due to the difference between coefficients of thermal expansion of the resin layer and the board when a thermal impact is applied thereto, since the inner side surface of the recessed portion has a tapered shape, a force from the resin layer on the electronic component side to the bonding material is unlikely to be applied so that the electronic component is unlikely to peel off from the circuit board in a thermal impact test.

A circuit board according to the present disclosure includes at least a pair of second terminals. A bonding material is disposed on the second terminal. The second terminal and the bonding material are disposed inside a recessed portion formed in a resin layer such that the periphery thereof is surrounded by the resin layer. When a total thickness of the second terminal and the bonding material is a dimension h2, the dimension h2 is 1 μm to 20 μm. When a width of the recessed portion of the resin layer is a dimension d2, the dimension d2 is 2 μm to 30 μm.

According to the circuit board of the present disclosure, it is possible to obtain a mounting board exhibiting operation and effects similar to those described above when an electronic component is mounted.

The dimension h2 may be larger than a thickness of the resin layer. In this case, since the second terminal can be pressed and adhered to the bonding material when an electronic component is mounted, a void between the bonding material and the second terminal after bonding is reduced. For this reason, even if the mounting board receives an impact, the bonding material is unlikely to break so that the strength can be improved.

### Advantageous Effects of Invention

According to the present disclosure, it is possible to provide a mounting board in which an electronic component can be unlikely to peel off from a circuit board, and a circuit board.

### BRIEF DESCRIPTION OF DRAWINGS

FIG. 1 is a schematic cross-sectional view illustrating a mounting board according to an embodiment of the present disclosure.

FIG. 2 is a schematic plan view illustrating a positional relationship between recessed portions and terminals when the mounting board is viewed from above.

FIG. 3 is a schematic cross-sectional view illustrating a circuit board according to the embodiment of the present disclosure.

FIG. 4 is a schematic cross-sectional view illustrating the mounting board according to a modification example.

FIG. 5 is a schematic cross-sectional view illustrating the mounting board according to another modification example.

FIG. 6 is a schematic cross-sectional view illustrating the mounting board according to another modification example.

FIG. 7 is a schematic cross-sectional view illustrating the mounting board according to a modification example.

FIG. 8 is a table showing conditions and test results of examples and comparative examples.

### DESCRIPTION OF EMBODIMENT

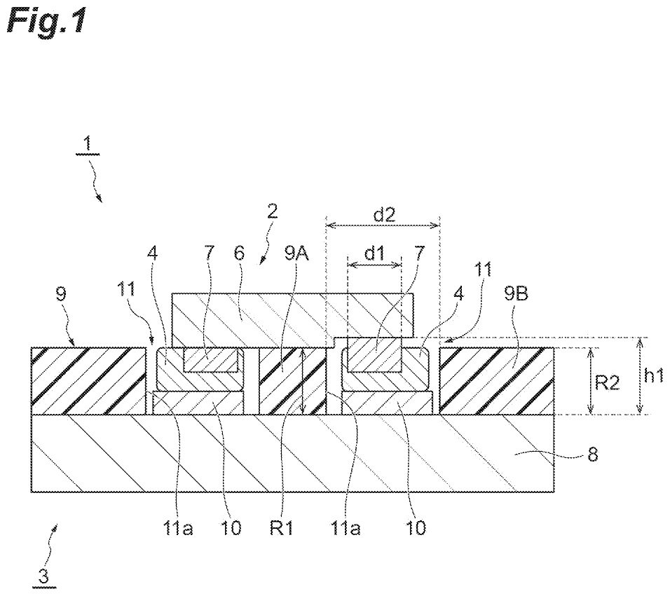

With reference to FIG. 1, a mounting board 1 according to an embodiment of the present disclosure will be described. FIG. 1 is a schematic cross-sectional view illustrating the mounting board 1 according to the embodiment of the present disclosure. As illustrated in FIG. 1, the mounting board 1 includes an electronic component 2 and a circuit board 3. The mounting board 1 is constituted by mounting the electronic component 2 on the circuit board 3 with a bonding material 4 therebetween.

The electronic component 2 includes a main body portion 6 and a pair of terminals 7 (first terminals). The main body portion 6 is a member for exhibiting a function as the electronic component 2. The terminal 7 is a metal part formed on a main surface of the main body portion 6. Regarding a material of the terminal 7, Cu, Ti, Au, Ni, Sn, Bi, P, B, In, Ag, Zn, Pd, Mo, Pt, Cr, an alloy selected from at least two of these, or the like is employed. For example, the electronic component 2 is constituted of a micro LED or the like. A micro LED is a component emitting light in accordance with an input from the circuit board 3.

The circuit board 3 includes a base material 8, a resin layer 9, and a pair of terminals 10 (second terminals). The base material 8 is a flat plate-shaped main body portion of the circuit board 3. The resin layer 9 is a layer made of a resin formed on an upper surface of the base material 8. Regarding a material of the resin layer 9, for example, an epoxy resin, an acrylic resin, a phenol resin, a melamine resin, a urea resin, or an alkyd resin is employed. It is particularly preferable to employ an epoxy resin or an acrylic resin as a material of the resin layer 9. The terminal 10 is a metal part formed on a main surface of the base material 8. Regarding a material of the terminal 10, Ni, Cu, Ti, Cr, Al, Mo, Pt, Au, an alloy selected from at least two of these, or the like is employed.

The bonding material 4 is a member for bonding the terminal 7 of the electronic component 2 and the terminal 10 of the circuit board 3 to each other. The bonding material 4 may include Sn or may be constituted of an alloy including Sn. However, the bonding material 4 is not necessarily limited to that including Sn. In addition to Sn, the bonding material 4 may be constituted of an alloy including an element which lowers the melting point of Sn. Examples of an element which lowers the melting point of Sn include Bi. The bonding material 4 functions as a solder. Accordingly, the terminals 10, the bonding materials 4, and the terminals 7 are laminated in this order between the base material 8 and the main body portion 6 from the upper surface of the base material 8. In the relevant locations, solder bonding is performed after the terminals 10, the bonding materials 4, and the terminals 7 are laminated. Therefore, a structure in which respective metals of the terminals 10, the bonding materials 4, and the terminals 7 are melted and diffused is formed. Such a structure after solder bonding may be a structure including a fragile intermetallic compound (IMC). When an intermetallic compound having a fragile structure is present, reliability is likely to deteriorate. For this reason, an effect achieved by the structure surrounding the structure of solder bonding with the resin layer 9 becomes more prominent.

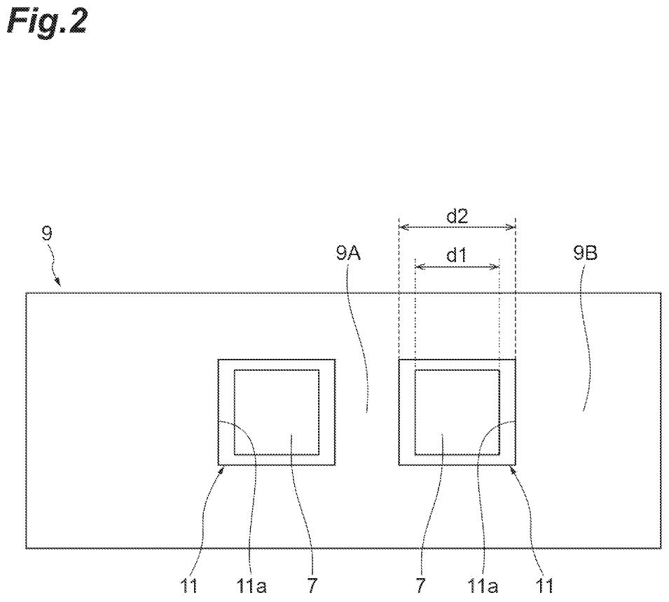

A pair of recessed portions 11 are formed in the resin layer 9. The recessed portions 11 are constituted of penetration holes penetrating the resin layer 9. Accordingly, on a bottom side of the recessed portion 11, the upper surface of the base material 8 is exposed. The recessed portion 11 has a rectangular shape when viewed in a thickness direction of the circuit board 3 (refer to FIG. 2). The terminal 7, the terminal 10, and the bonding material 4 are disposed inside the recessed portion 11 formed in the resin layer 9 such that the periphery thereof is surrounded by the resin layer 9. Slight gaps are formed between the terminal 7, the terminal 10, and the bonding material 4; and four inner side surfaces 11a of the recessed portion 11.

In the resin layer 9, a part present between the pair of terminals 7 will be referred to as a first part 9A, and a part surrounding the electronic component 2 will be referred to as a second part 9B. In the present embodiment, heights of the first part 9A and the second part 9B from the base material 8 are the same. In addition, the first part 9A of the resin layer 9 present between the pair of terminals 7 come into contact with the main body portion 6 of the electronic component 2. Specifically, an upper surface of the first part 9A of the resin layer 9 comes into contact with a lower surface of the main body portion 6 of the electronic component.

Next, with reference to FIGS. 1 and 2, a dimensional relationship in each element of the mounting board 1 will be described. FIG. 2 is a schematic plan view illustrating a positional relationship between the recessed portions 11 and the terminals 7 when the mounting board 1 is viewed from above. In FIG. 2, constituent elements other than the resin layer 9 and the terminals 7 of the electronic component 2 are omitted.

Description will be given while the total thickness of the terminal 7, the terminal 10, and the bonding material 4 is a dimension h1. At this time, the dimension h1 is preferably 1 μm or larger and is more preferably 4 μm or larger. In addition, the dimension h1 is preferably 20 μm or smaller, is more preferably 15 μm or smaller, and is even more preferably 10 μm or smaller. In one mounting board 1, a plurality of sets of combinations of “the terminal 7, the terminal 10, and the bonding material 4” are provided, but the dimensions h1 of the respective combinations may be different from each other. In this case, it is preferable that the dimension h1 of the combination having the highest height measurement result satisfy the foregoing conditions. However, in the mounting board 1, at least one dimension h1 satisfying the foregoing conditions need only be present. The dimension h1 can be measured by cutting the mounting board 1 in a perpendicular manner, performing SEM observation of the cross section, and the like.

When a width of the terminal 7 is a dimension d1 and a width of the recessed portion 11 of the resin layer 9 is a dimension d2, (dimension d2—dimension d1) is preferably 10 μm or smaller, is preferably 6 μm or smaller, and is even more preferably 2 μm or smaller. The lower limit value for (dimension d2—dimension d1) is not particularly limited, and 0 μm may be set as the lower limit value when manufacturing is not affected.

The dimension d1 is preferably 2 μm or larger and is more preferably 5 μm or larger. The dimension d1 is preferably 20 μm or smaller and is more preferably 10 μm or smaller. The dimension d2 is preferably 2 μm or larger and is more preferably 7 μm or larger. The dimension d2 is preferably 30 μm or smaller and is more preferably 15 pun or smaller. The distance between one recessed portion 11 and the other recessed portion 11 is preferably 4 μm to 20 μm. The dimension d1 and the dimension d2 can be measured by cutting the mounting board 1 in a manner parallel to the upper surface thereof and performing SEM observation.

In one mounting board 1, a plurality of sets of combinations of “the terminal 7 and the recessed portion 11” are provided, but the values of(dimension d2—dimension d1) of the respective combinations may be different from each other. In this case, in the mounting board 1, at least one value of (dimension d2—dimension d1) satisfying the foregoing conditions need only be present. A corner R may be formed in corner portions of the recessed portions 11 of the resin layer 9 and corner portions of the terminals 7 and 10. For example, the corner R may be set to 1 μm, 5 μm, 10 μm, or the like.

As illustrated in FIG. 2, when the terminal 7 has a square shape, the dimension of any side corresponds to the dimension d1. When the terminal 7 has a rectangular shape, the dimensions of short sides correspond to the dimension d1. When the terminal 7 has a circular shape, the diameter corresponds to the dimension d1. When the terminal 7 has an oval shape, the shorter diameter corresponds to the dimension d1. When the terminal 7 has a polygonal shape such as a pentagon or a polygon having more sides, distances between apexes and sides respectively facing the apexes are measured, and the shortest distance is taken as the dimension d1. A method for determining the dimension d2 corresponding to the shape of the recessed portion 11 is also similar to that for the dimension d1.

As illustrated in FIG. 1, the height of the first part 9A of the resin layer 9 present between the pair of terminals 7 is regarded as a dimension R1, and the height of the second part 9B of the resin layer 9 surrounding the electronic component 2 is regarded as a dimension R2. In this case, the dimension R1 is preferably 2 μm or larger and is more preferably 4 μm or larger. The dimension R1 is preferably 20 μm or smaller and is more preferably 10 μm or smaller. The dimension R2 is preferably 3 μm or larger and is more preferably 4 μm or larger. The dimension R2 is preferably 30 μm or smaller and is more preferably 10 μm or smaller.

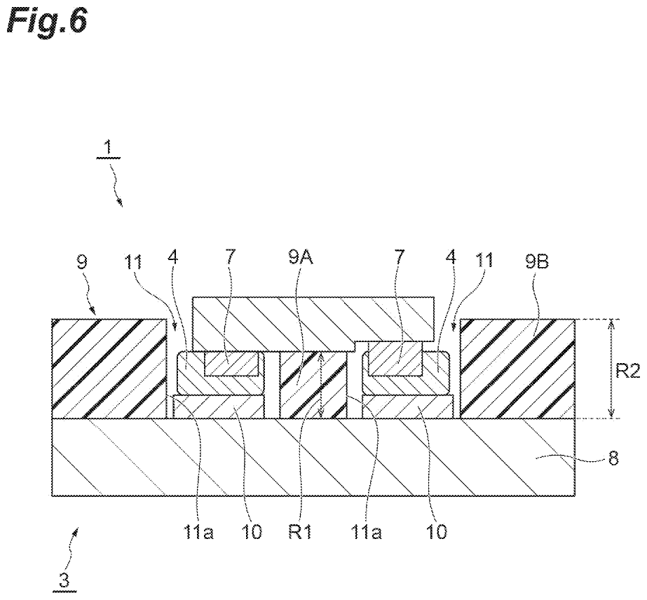

In the example illustrated in FIG. 1, the dimension R1 and the dimension R2 are set to the same value. In this case, the resin layer 9 can be easily formed. However, the dimension R1 and the dimension R2 may be set to values different from each other. As illustrated in FIG. 6, the dimension R1 may be set to a value smaller than the dimension R2. In this case, the upper surface of the second part 9B may be disposed at a position higher than the lower surface of the main body portion 6 of the electronic component 2.

Next, a method for manufacturing the mounting board 1, and a constitution of the circuit board 3 in a manufacturing process will be described.

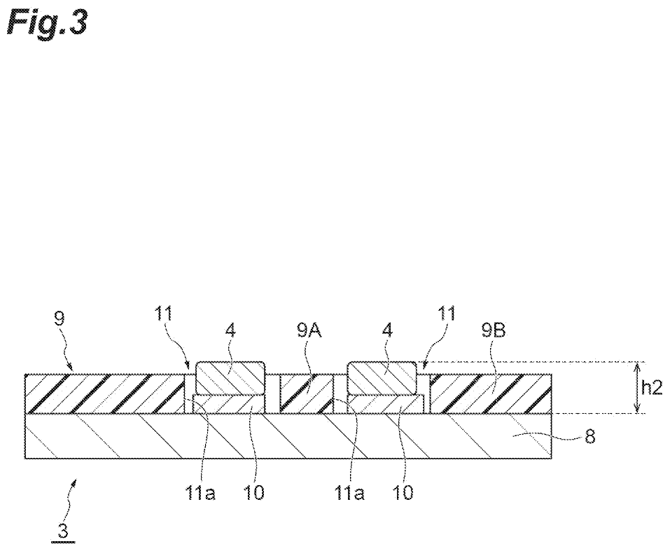

First, the circuit board 3 illustrated in FIG. 3 is prepared. In this state, the bonding material 4 is in a state of being disposed on the terminal 10. Since this bonding material 4 is in a state of a stage before being bonded to the electronic component 2, it is thicker than at least the bonding material 4 in the state of the mounting board 1 in FIG. 1. This bonding material 4 may be a metal including Sn which becomes a low-temperature solder and may have any fine structure as long as the entire composition has a low melting point. For example, at a stage of distributing the circuit board 3, the bonding material 4 may have a laminated structure having a layer of Sn and a layer of another metal such as Bi. Alternatively, it may be heated in advance, and in a state of an alloy of Sn and another metal, the circuit board 3 may be distributed.

In this state, the terminal 10 and the bonding material 4 are disposed inside the recessed portion 11 formed in the resin layer 9 such that the periphery thereof is surrounded by the resin layer 9. When the total thickness of the terminal 10 and the bonding material 4 is a dimension h2, the dimension h2 is preferably 1 μm or larger and is more preferably 3 μm or larger. The dimension h2 is preferably 20 μm or smaller and is more preferably 10 μm or smaller.

The electronic component 2 is placed on the circuit board 3. At this time, the pair of terminals 7 of the electronic component 2 are respectively placed on a pair of bonding materials 4. Soldering is performed by heating the circuit board 3 and the electronic component 2 in this state. A heating method thereof may be any of a reflow method in which they are input to a furnace or the like for heating, a thermal compression method in which the electronic component 2 is heated while being compressed, and a light heating method in which heating is performed by applying light thereto, or these may be combined. As above, the electronic component 2 is mounted on the circuit board 3, and therefore the mounting board 1 is completed.

Operation and effects of the mounting board 1 and the circuit board 3 according to the present embodiment will be described.

In the mounting board 1, the terminal 7, the terminal 10, and the bonding material 4 are disposed inside the recessed portion 11 formed in the resin layer 9 such that the periphery thereof is surrounded by the resin layer 9. Accordingly, an impact cushioning structure of the resin layer 9 can be provided around a bonded part. Moreover, the bonded part can be unlikely to break by setting the dimension h1, which is the total thickness of the terminal 7, the terminal 10, and the bonding material 4, to 1 μm to 20 μm. In addition, by setting the value of (dimension d2—dimension d1) to be 10 μm or smaller, the electronic component 2 can be unlikely to peel off from the circuit board 3 when the mounting board 1 has received a physical impact.

The first part 9A of the resin layer 9 present between the pair of terminals 7 may come into contact with the main body portion 6 of the electronic component 2. In this case, since the lower surface of the main body portion 6 of the electronic component 2 is supported by the first part 9A of the resin layer 9 by coming into contact therewith, even if the mounting board 1 receives a physical impact, a force is unlikely to be applied to the bonding material 4 so that the electronic component 2 is unlikely to peel off from the circuit board 3.

When the height of the first part 9A of the resin layer 9 present between the pair of terminals 7 is the dimension R1 and the height of the second part 9B of the resin layer 9 surrounding the electronic component 2 is the dimension R2, the dimension R1 may be smaller than the dimension R2. In this case, since the main body portion 6 of the electronic component 2 is constituted to be surrounded and supported by the second part 9B of the surrounding resin layer 9, even if the mounting board 1 receives a physical impact, a force is unlikely to be applied to the bonding material 4 so that the electronic component 2 is unlikely to peel off from the circuit board 3.

The circuit board 3 is a circuit board 3 having at least a pair of terminals 10. The bonding material 4 is disposed on the terminal 10. The terminal 10 and the bonding material 4 are disposed inside the recessed portion 11 formed in the resin layer 9 such that the periphery thereof is surrounded by the resin layer 9. When the total thickness of the terminal 10 and the bonding material 4 is the dimension h2, the dimension h2 is 1 μm to 20 μm. When the width of the recessed portion 11 of the resin layer 9 is the dimension d2, the dimension d2 is 2 μm to 30 μm.

According to the circuit board 3 of the present embodiment, it is possible to obtain the mounting board 1 exhibiting operation and effects similar to those described above when the electronic component 2 is mounted.

The present disclosure is not limited to the embodiment described above.

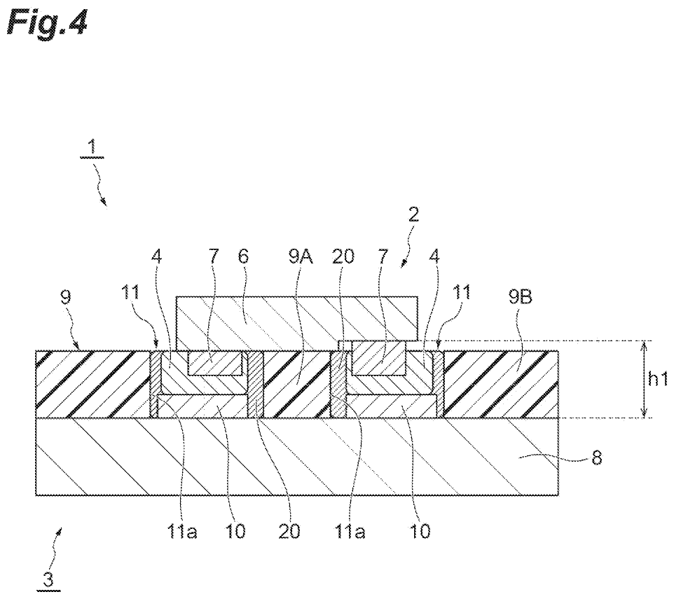

For example, as illustrated in FIG. 4, a constituent material 20 may be disposed between the bonding material 4 and the resin layer 9. Accordingly, the electronic component 2 can be less likely to peel off from the circuit board 3 by being supported by the constituent material 20.

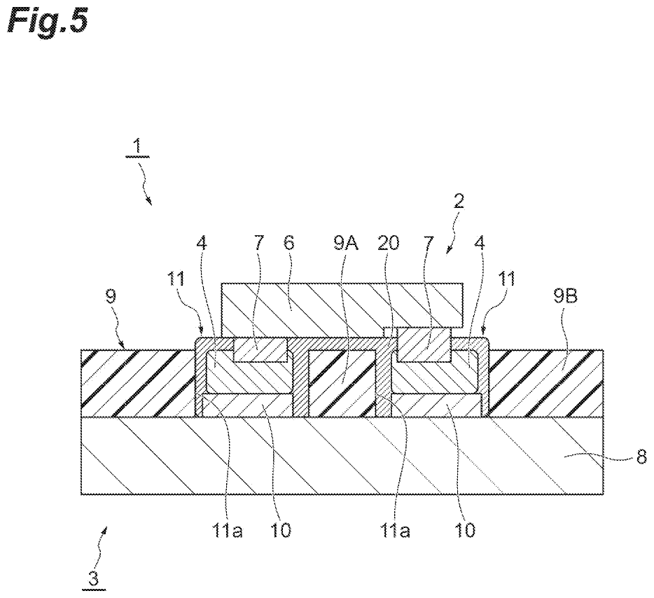

In addition, as illustrated in FIG. 5, the constituent material 20 may be disposed between the first part 9A of the resin layer 9 present between the pair of terminals 7 and the main body portion 6 of the electronic component 2. Accordingly, the main body portion 6 of the electronic component 2 can be held by the constituent material 20, and thus the strength can be improved.

Moreover, as illustrated in FIG. 5, the constituent material 20 may come into contact with the main body portion 6. In this case, the lower surface of the main body portion 6 of the electronic component 2 can be fixed by the constituent material 20. Therefore, even if the mounting board 1 receives a physical impact, a force is unlikely to be applied to the bonding material 4 so that the electronic component 2 is unlikely to peel off from the circuit board 3.

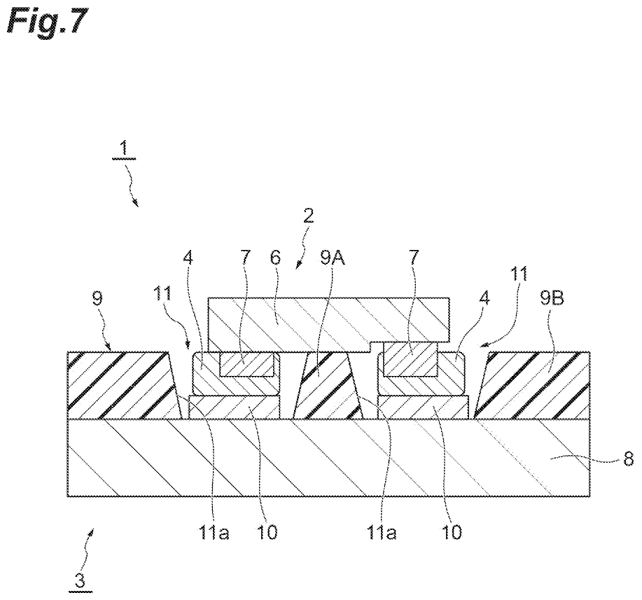

In addition, as illustrated in FIG. 7, the inner side surface 11a of the recessed portion 11 may have a tapered shape widening toward the electronic component 2 side. Although a force is applied from the resin layer 9 to the bonding material 4 due to the difference between the coefficients of thermal expansion of the resin layer 9 and the base material 8 when a thermal impact is applied thereto, since the inner side surface 11a of the recessed portion 11 has a tapered shape, a force from the resin layer on the electronic component 2 side to the bonding material 4 is unlikely to be applied so that the electronic component 2 is unlikely to peel off from the circuit board 3 in a thermal impact test. When the dimension d2 of the width of the recessed portion 11 is defined, the dimension of the width of an upper end of the recessed portion 11 (that is, a position on the upper surface of the resin layer 9) is taken as the dimension d2. That is, the dimension d2 is set at a location where the dimension of the width is maximized in the recessed portion 11.

In addition, the dimension h2 of the height of the bonding material 4 in the circuit board 3 may be larger than the dimension R2 of the height of the resin layer 9 (for example, refer to FIG. 3). Since the dimension h2 is larger than the dimension R2, the terminal 7 can be pressed and adhered to the bonding material 4 when the electronic component 2 is mounted. Therefore, a void between the bonding material 4 and the terminal 7 after bonding is reduced. For this reason, even if the mounting board 1 receives an impact, the bonding material 4 is unlikely to break so that the strength can be improved.

### Examples

Examples of the mounting board according to the present disclosure will be described. The present disclosure is not limited to the following examples.

First, mounting boards of Examples 1 to 11 and Comparative Examples 1 and 2 were produced by the manufacturing method as follows. First, the base material 8 having the terminals 10 formed therein was prepared. A glass epoxy substrate was employed as the base material 8. Cu terminals coated with a Ni film were employed as the terminals 10. 100 pairs of terminals 10 were formed on the base material 8. Next, a pair of Bi/Sn laminate pads having a desired thickness were formed on the terminals 10 as the bonding materials 4. A pair of bonding material 4 were formed on the base material 8 at 100 locations.

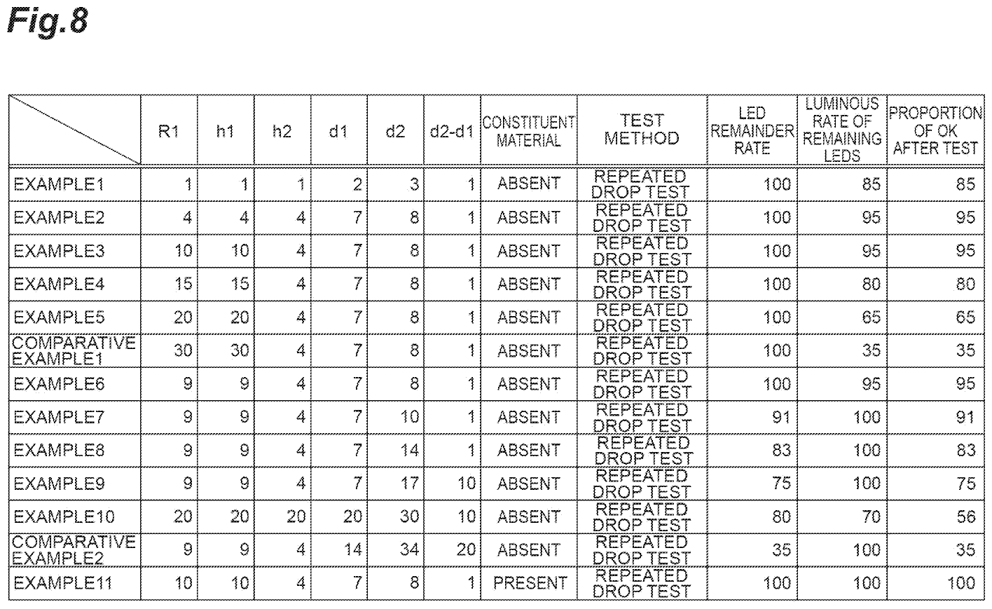

Next, the resin layer 9 was formed on the base material 8 such that the terminals 10 and the bonding materials 4 were surrounded. An epoxy resin was employed as this resin layer 9. Accordingly, the circuit board 3 illustrated in FIG. 3 was obtained. Next, an LED chip was placed on the circuit board 3 as the electronic component 2. 100 LED chips were mounted on the circuit board 3. The LED chips had Au terminals as the terminals 7. Next, the mounting board 1 in this state was subjected to a reflow at 150° C. to 190° C. Accordingly, the circuit board 3 and the electronic component 2 were bonded to each other. The table in FIG. 8 shows dimensions and the presence or absence of a constituent material of Examples 1 to 11 and Comparative Examples 1 and 2.

A test was performed as follows with respect to the mounting boards of Examples 1 to 11 and Comparative Examples 1 and 2 described above. The obtained mounting boards were subjected to a free drop 10 times from a height of 30 cm. Next, research was performed while having the proportion of the number of remainder LED chips, which remained after the test, to the number of all LED chips on the mounting board before the test, as “an LED remainder rate”. In the remaining LED chips, research was performed while having the proportion of the number of LED chips emitting light, as “a luminous rate of remaining LEDs”. Regarding the luminous rate of the remaining LEDs, 50% or higher was regarded as OK. In addition, research was performed while having the proportion of the number of LED chips emitting light to the number of LED chips before the test, as “a proportion of OK after test”. The table in FIG. 8 shows test results thereof.

First, in Comparative Example 1, since the dimension h1 was excessively long, it could be confirmed that the bonding portion was likely to break due to an impact and the number of LED chips not emitting light increased. In Comparative Example 2, since (dimension d2—dimension d1) was excessively large, it could be confirmed that the LED chips could not be protected from an impact of the test and the LED chips was likely to be fall off from the circuit board. Compared to this, in Examples 1 to 11, it was confirmed that there were many remaining LED chips and the remaining LED chips could emit light at a high proportion.

In Example 1, since the dimension h1 was small, it could be understood that there was variation in bonding strength due to increased variation in amount of solder with respect to the formed bonding portion and the luminous rate slightly deteriorated due to some places where the bonding portion of a solder could not withstand the test. In Examples 2 and 3, since the dimension h1 was appropriate for the height and (dimension d2—dimension d1) was small, it could be understood that the bonding portion could be protected and a high proportion of OK after test could be achieved. In Example 4, since the dimension h1 was larger than those of Examples 2 and 3, it could be understood that the bonding portion was slightly thinned and the number of LED chips which could withstand the test was slightly reduced. In Example 5, since the dimension h1 was larger than that of Example 4, it could be understood that the bonding portion was slightly thinned and the number of LED chips which could withstand the test was slightly reduced.

In Example 6, since (dimension d2—dimension d1) was small, it could be understood that the bonding portion could be protected and a high proportion of OK after test could be achieved. In Examples 7, 8, and 9, although (dimension d2—dimension d1) was larger than that of Example 6, since there were many bonding portions which came into contact with the wall of the recessed portion and an impact received by those in the test was restricted by the wall of the recessed portion, it could be understood that reduction of the luminous rate could be slightly curbed. In Example 10, although (dimension d2—dimension d1) was equivalent to that of Example 9, since the bonding portion was tapered and was likely to break by an impact due to the large dimension h1, it could be understood that the proportion of OK after test slightly deteriorated. In Example 11, it could be understood that favorable results could be achieved in all items.

### REFERENCE SIGNS LIST

1 Mounting board
2 Electronic component
3 Circuit board
4 Bonding material
6 Main body portion
7 Terminal (first terminal)
9 Resin layer
10 Terminal (second terminal)
11 Recessed portion

1. A mounting board comprising:
an electronic component having at least a pair of first terminals; and
a circuit board having at least a pair of second terminals,
wherein the first terminal and the second terminal are bonded to each other by a bonding material,
wherein the first terminal, the second terminal, and the bonding material are disposed inside a recessed portion formed in a resin layer such that the periphery thereof is surrounded by the resin layer,
wherein when a total thickness of the first terminal, the second terminal, and the bonding material is a dimension h1, the dimension h1 is 1 μm to 20 μm, and
wherein when a width of the first terminal is a dimension d1 and a width of the recessed portion of the resin layer is a dimension d2, a value of (dimension d2—dimension d1) is 10 μm or smaller.

2. The mounting board according to claim 1,
wherein a constituent material is disposed between the bonding material and the resin layer.

3. The mounting board according to claim 1,
wherein a constituent material is disposed between the resin layer present between the pair of first terminals and a main body portion of the electronic component.

4. The mounting board according to claim 3,
wherein the constituent material comes into contact with the main body portion.

5. The mounting board according to claim 1,
wherein the resin layer present between the pair of first terminals comes into contact with a main body portion of the electronic component.

6. The mounting board according to claim 1,
wherein when a height of the resin layer present between the pair of first terminals is a dimension R1 and a height of the resin layer surrounding the electronic component is a dimension R2, the dimension R1 is smaller than the dimension R2.

7. The mounting board according to claim 1,
wherein an inner side surface of the recessed portion has a tapered shape.

8. A circuit board comprising:
at least a pair of second terminals,
wherein a bonding material is disposed on the second terminal,
wherein the second terminal and the bonding material are disposed inside a recessed portion formed in a resin layer such that the periphery thereof is surrounded by the resin layer,
wherein when a total thickness of the second terminal and the bonding material is a dimension h2, the dimension h2 is 1 μm to 20 μm, and
wherein when a width of the recessed portion of the resin layer is a dimension d2, the dimension d2 is 2 μm to 30 μm.

9. The circuit board according to claim 8,
wherein the dimension h2 is larger than a thickness of the resin layer.

10. The mounting board according to claim 2,
wherein a constituent material is disposed between the resin layer present between the pair of first terminals and a main body portion of the electronic component.

11. The mounting board according to claim 10,
wherein the constituent material comes into contact with the main body portion.

12. The mounting board according to claim 2,
wherein the resin layer present between the pair of first terminals comes into contact with a main body portion of the electronic component.

13. The mounting board according to claim 2,
wherein when a height of the resin layer present between the pair of first terminals is a dimension R1 and a height of the resin layer surrounding the electronic component is a dimension R2, the dimension R1 is smaller than the dimension R2.

14. The mounting board according to claim 3,
wherein when a height of the resin layer present between the pair of first terminals is a dimension R1 and a height of the resin layer surrounding the electronic component is a dimension R2, the dimension R1 is smaller than the dimension R2.

15. The mounting board according to claim 4,
wherein when a height of the resin layer present between the pair of first terminals is a dimension R1 and a height of the resin layer surrounding the electronic component is a dimension R2, the dimension R1 is smaller than the dimension R2.

16. The mounting board according to claim 5,
wherein when a height of the resin layer present between the pair of first terminals is a dimension R1 and a height of the resin layer surrounding the electronic component is a dimension R2, the dimension R1 is smaller than the dimension R2.

17. The mounting board according to claim 2,
wherein an inner side surface of the recessed portion has a tapered shape.

18. The mounting board according to claim 3,
wherein an inner side surface of the recessed portion has a tapered shape.

19. The mounting board according to claim 4,
wherein an inner side surface of the recessed portion has a tapered shape.

20. The mounting board according to claim 5,
wherein an inner side surface of the recessed portion has a tapered shape.

21. The mounting board according to claim 6,
wherein an inner side surface of the recessed portion has a tapered shape.
